(19) United States
(12) Patent Application Publication
(10) Pub. No.: US 2024/0172438 A1
(43) Pub. Date: May 23, 2024

(54) MEMORY BLOCK, MEMORY-CELL GROUP AND MEMORY DEVICE

(71) Applicant: WUHAN XINXIN SEMICONDUCTOR MANUFACTURING CO., LTD., Wuhan (CN)

(72) Inventors: Qiong ZHAN, Wuhan (CN); Kaiwei CAO, Wuhan (CN)

(21) Appl. No.: 18/089,560

(22) Filed: Dec. 27, 2022

(30) Foreign Application Priority Data
Nov. 18, 2022 (CN) 202211452183.1

(51) Int. Cl. H10B 43/27; H10B 41/27

(52) U.S. Cl. CPC H01L 27/11582; H01L 27/11556

(57) ABSTRACT

The memory block includes a memory array including stacked strip structures spaced apart from each other along a column direction and semiconductor structures. Each stacked strip structure extends along a row direction, and includes insulating strips and conductive strips alternately stacked along a height direction. Some of the semiconductor structures are arranged between every two adjacent stacked strip structures. Every two adjacent stacked strip structures and the semiconductor structures arranged therebetween are involved in forming a row of memory subarray. The conductive strips in the two adjacent stacked strip structures serve as control gates of the row of memory subarray. The row of memory subarray includes memory-cell groups distributed along the row direction. Each memory-cell group includes a corresponding semiconductor structure that extends along the height direction. On a plane perpendicular to the height direction, the cross section of the semiconductor structure is ring-shaped.

### CROSS REFERENCE TO RELATED APPLICATIONS

The present application claims priority to Chinese Patent Application NO. 202211452183.1 filed on Nov. 18, 2022, the entire contents of which are herein incorporated by reference in their entireties.

### TECHNICAL FIELD

The present disclosure relates to the technical field of semiconductor devices, in particular to a memory block, a memory-cell group, and a memory device.

### BACKGROUND

Two dimensional (2D) memory block is ubiquitous in electronic devices. For example, the 2D memory block may include NOR flash memory array, NAND flash memory array, dynamic random access memory (DRAM) array, and so on. However, 2D memory array has already approached a scaling limit, and a memory density cannot be further improved.

### SUMMARY

Firstly, the present disclosure provides a memory block. The memory block includes a memory array including a plurality of stacked strip structures and a plurality of semiconductor structures. The stacked strip structures are spaced apart from each other along a column direction. Each of the stacked strip structures extends along a row direction, and includes a plurality of insulating strips and a plurality of conductive strips alternately stacked along a height direction. Some of the semiconductor structures are arranged between every two adjacent stacked strip structures. The every two adjacent stacked strip structures and some of the semiconductor structures arranged therebetween are involved in forming a row of memory subarray. The conductive strips in the every two adjacent stacked strip structures serve as control gates of the row of memory subarray. The row of memory subarray includes a plurality of memory-cell groups distributed along the row direction. Each memory-cell group includes a corresponding semiconductor structure. The corresponding semiconductor structure extends along the height direction. On a plane perpendicular to the height direction, a cross section the corresponding semiconductor structure is ring-shaped.

Secondly, the present disclosure provides a memory-cell group. The memory-cell group includes a first memory cell and a second memory cell. The first memory cell includes a source-region semiconductor structure, a drain-region semiconductor structure, and a first channel semiconductor structure arranged between the source-region semiconductor structure and the drain-region semiconductor structure. The second memory cell includes the source-region semiconductor structure, the drain-region semiconductor structure, and a second channel semiconductor structure arranged between the source-region semiconductor structure and the drain-region semiconductor structure. The first memory cell and the second memory cell share the source-region semiconductor structure and the drain-region semiconductor structure. The source-region semiconductor structure, the drain-region semiconductor structure, the first channel semiconductor structure, and the second channel semiconductor structure form an annular structure cooperatively.

Thirdly, the present disclosure provides a memory device. The memory device includes one or more memory blocks described above, or one or more memory-cell groups described above.

### BRIEF DESCRIPTION OF THE DRAWINGS

In order to explain technical solutions of embodiments of the present disclosure more clearly, the following will briefly introduce figures needed to use in the description of the embodiments. Obviously, the figures in the following are only some embodiments of the present disclosure. For those skilled in the art, other figures may also be obtained from these figures.

FIG. 1 is a block diagram of a memory device according to an embodiment of the present disclosure.

FIG. 2 is a schematic partial-structure view of a memory block according to an embodiment of the present disclosure.

FIG. 3 is a schematic sectional-structure view of a memory-cell group on a plane perpendicular to a height direction in FIG. 2.

FIG. 4 is a schematic sectional-structure view of the memory-cell group along C-C in FIG. 3.

FIG. 5 is a schematic sectional-structure view of the memory-cell group along D-D in FIG. 3.

FIG. 6 is a schematic partial-structure view of the memory-cell group in FIG. 2.

FIG. 7 is a schematic sectional-structure view of the memory-cell group of the memory block along D-D according to a further embodiment of the present disclosure.

FIG. 8 is a schematic partial-structure view of the memory block according to a further embodiment of the present disclosure.

FIG. 9 is a schematic partial-structure view of the memory block according to a further embodiment of the present disclosure.

FIG. 10 is a schematic structural view of a memory cell in response to the memory cell being executed a reading operation according to the embodiment shown in FIG. 9.

FIG. 11 is a further schematic structural view of the memory cell in response to the memory cell being executed the reading operation according to the embodiment shown in FIG. 9.

FIG. 12 is a schematic structural view of the memory cell in response to the memory cell being executed a programming operation according to the embodiment shown in FIG. 9.

FIG. 13 is a schematic structural view of the memory cell in response to the memory cell being executed an erasing operation according the embodiment shown in FIG. 9.

### DETAILED DESCRIPTION

Technical solutions in embodiments of the present disclosure will be described clearly and completely in combination with figures in the embodiments of the present disclosure. It is understood that the specific embodiments described herein are only used to explain the present disclosure, but not to limit the present disclosure. In addition, it should be noted that, for the convenience of description, only a part of structures which related to the present disclosure are shown in the figures, but not all structures. Based on the embodiments in the present disclosure, all other embodiments obtained by those skilled in the art without doing any creative work belong to the protection scope of the present disclosure. The “a plurality of” or “multiple” mentioned in the present disclosure is greater than or equal to 2.

As shown in FIG. 1, FIG. 1 is a block diagram of a memory device according to an embodiment of the present disclosure. The present disclosure provides a memory device (i.e., a chip) 200. The memory device 200 may be a non-volatile memory. The memory device 200 may include one or more memory blocks 100.

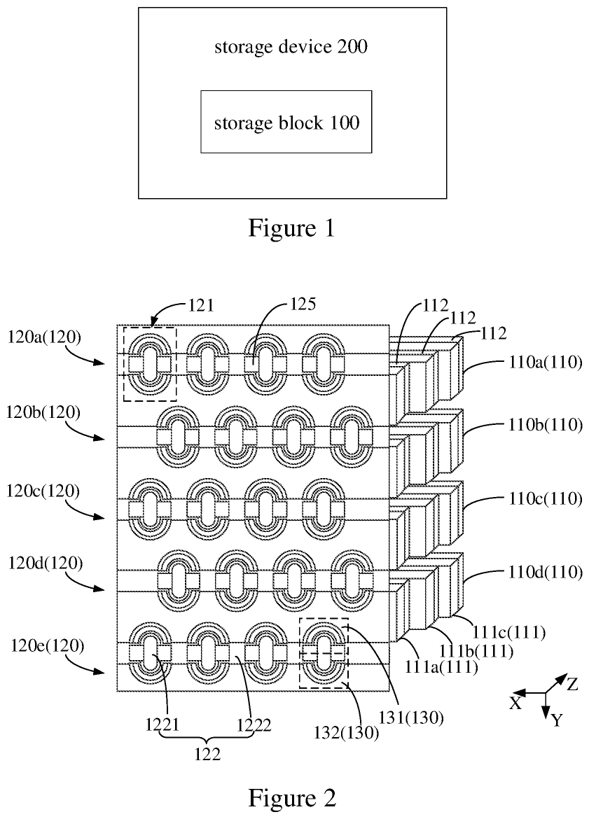

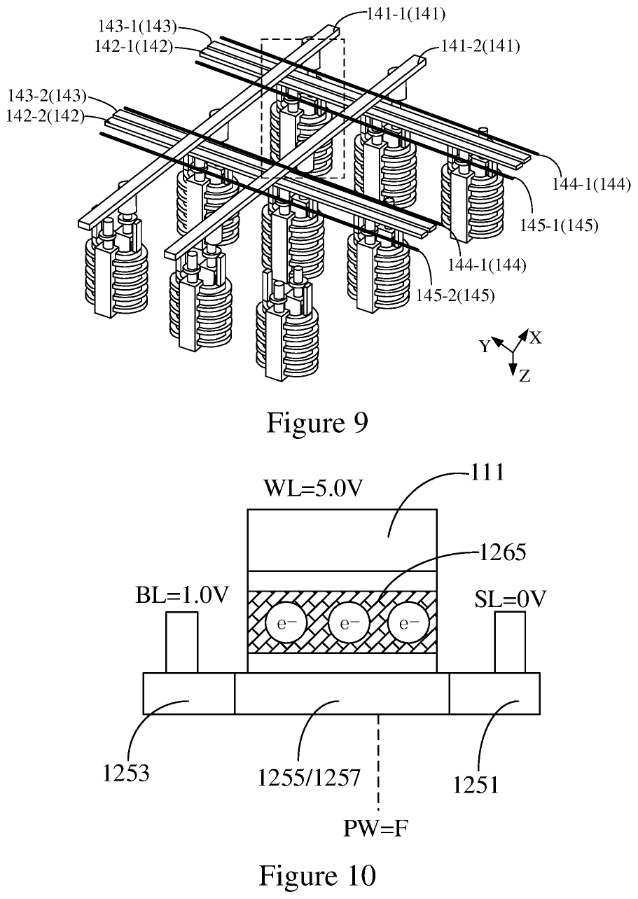

As shown in FIG. 2, FIG. 2 is a schematic partial-structure view of a memory block according to an embodiment of the present disclosure. The memory block 100 may include a memory array (the memory array includes multiple rows of memory subarrays 120. As shown in FIGS. 2, 120a, 120b, 120c, 120d, and 120e represent one row of memory subarray respectively) and various types of connecting lines (such as source lines 141, bit lines 142, well-region lines 143, source controlling lines 144, bit-line controlling lines 145, and so on shown in FIG. 9).

In some embodiments, the memory array includes a plurality of stacked strip structures 110 spaced apart from each other along a column direction (such as a Y direction shown in FIG. 2). As shown in FIGS. 2, 110a, 110b, 110c, and 110d represent one stacked strip structure respectively. Each stacked strip structure 110 extends along a row direction (such as an X direction shown in FIG. 2). Each of the stacked strip structures 110 includes a plurality of insulating strips 112 and a plurality of conductive strips 111 alternately stacked along a height direction (such as a Z direction shown in FIG. 2). The conductive strip 111 and the insulating strip 112 may be alternately arranged one by one. As shown in FIGS. 2, 111a, 111b, and 111c respectively represent one conductive strip. The column direction, the row direction and the height direction are perpendicular or substantially perpendicular to each other, and the height direction is perpendicular to a plane defined by the column direction and the row direction.

The memory array further includes a plurality of semiconductor structures 125. Some of the semiconductor structures 125 are arranged between every two adjacent stacked strip structures 110. As shown in FIG. 2, four semiconductor structures 125 are arranged between every two adjacent stacked strip structures 110.

Every two adjacent stacked strip structures 110 and the semiconductor structures 125 arranged therebetween are involved in forming a row of memory subarray 120. Each conductive strip 111 in the every two adjacent stacked strip structures 110 serves as a control gate of the row of memory subarray 120. Each row of memory subarray 120 includes a plurality of memory-cell groups 121 distributed along the row direction. Each memory-cell group 121 includes a corresponding semiconductor structure 125.

Every two adjacent stacked strip structures 110 are involved in forming the row of memory subarray 120 cooperatively. That is, each row of memory subarray 120 corresponds to two stacked strip structures 110. It should be noted that “two stacked strip structures 110 corresponding to each row of memory subarray 120” mentioned in the present disclosure refers to two adjacent stacked strip structures 110 involved in forming the corresponding row of memory subarray 120 cooperatively.

For the convenience of description, the two stacked strip structures 110 corresponding to each row of memory subarray 120 may be regarded as a first stacked strip structure and a second stacked strip structure respectively. The first stacked strip structure and the second stacked strip structure are two adjacent stacked strip structures 110.

For example, as shown in FIG. 2, the stacked strip structure 110a and the stacked strip structure 110b are involved in forming the row of memory subarray 120b cooperatively. In the column direction Y, the stacked strip structure 110a arranged at a first side (i.e., an upper side shown in FIG. 2) of the row of memory subarray 120b serves as the first stacked strip structure corresponding to the row of memory subarray 120b. The stacked strip structure 110b arranged at a second side (i.e., a lower side shown in FIG. 2) of the row of memory subarray 120b serves as the second stacked strip structure corresponding to the row of memory subarray 120b. The first side and the second side are opposite sides in the column direction Y.

The stacked strip structure 110b and the stacked strip structure 110c are involved in forming the row of memory subarray 120c cooperatively. In the column direction Y, the stacked strip structure 110b arranged at the first side (i.e., the upper side shown in FIG. 2) of the row of memory subarray 120c serves as the first stacked strip structure corresponding to the row of memory subarray 120c. The stacked strip structure 110c arranged at the second side (i.e., the lower side shown in FIG. 2) of the row of memory subarray 120c serves as the second stacked strip structure corresponding to the row of memory subarray 120c.

The stacked strip structure 110c and the stacked strip structure 110d are involved in forming the row of memory subarray 120d cooperatively. In the column direction Y, the stacked strip structure 110c arranged at the first side (i.e., the lower side shown in FIG. 2) of the row of memory subarray 120d serves as the first stacked strip structure corresponding to the row of memory subarray 120d. The stacked strip structure 110d arranged at the second side (i.e., the lower side shown in FIG. 2) of the row of memory subarray 120d serves as the second stacked strip structure corresponding to the row of memory subarray 120d.

That is, in the column direction Y, the stacked strip structure 110 arranged at the first side (i.e., the upper side shown in FIG. 2) of each row of memory subarray 120 serves as the first stacked strip structure corresponding to the corresponding row of memory subarray 120. The stacked strip structure 110 arranged at the second side (i.e., the lower side shown in FIG. 2) of each row of memory subarray 120 serves as the second stacked strip structure corresponding to the corresponding row of memory subarray 120. Therefore, other than a first one and a last one of the stacked strip structures 110, each stacked strip structure 110 at a non-edge region is not only the second stacked strip structure corresponding to a previous row of memory subarray 120, but also the first stacked strip structure corresponding to a next row of memory subarray 120.

In two stacked strip structures 110 corresponding to each memory-cell group 121 (i.e., in two stacked strip structures 110 corresponding to the row of memory subarray 120 in which the corresponding memory-cell group 121 is located), each conductive strip 111 serves as a control gate of the corresponding memory-cell group 121, to form a memory cell (i.e., a bit) 130. Each conductive strip 111 in the first stacked strip structure serves as a first control gate of the corresponding memory-cell group 121, to form a first memory cell 131. Each conductive strip 111 in the second stacked strip structure serves as a second control gate of the corresponding memory-cell group 121, to form a second memory cell 132.

For example, as shown in FIG. 2, the stacked strip structure 110a serves as the first stacked strip structure corresponding to the row of memory subarray 120b, and each conductive strip 111 in the stacked strip structure 110a serves as the first control gate of each memory-cell group 121 in the row of memory subarray 120b, to form the first memory cell 131. The stacked strip structure 110b serves as the second stacked strip structure corresponding to the row of memory subarray 120b, and each conductive strip 111 in the stacked strip structure 110b serves as the second control gate of each memory-cell group 121 in the row of memory subarray 120b, to form the second memory cell 132.

The stacked strip structure 110b serves as the first stacked strip structure corresponding to the row of memory subarray 120c, and each conductive strip 111 in the stacked strip structure 110b serves as the first control gate of each memory-cell group 121 in the row of memory subarray 120c, to form the first memory cell 131. The stacked strip structure 110c serves as the second stacked strip structure corresponding to the row of memory subarray 120c, and each conductive strip 111 in the stacked strip structure 110c serves as the second control gate of each memory-cell group 121 in the row of memory subarray 120c, to form the second memory cell 132.

The stacked strip structure 110c serves as the first stacked strip structure corresponding to the row of memory subarray 120d, and each conductive strip 111 in the stacked strip structure 110c serves as the first control gate of each memory-cell group 121 in the row of memory subarray 120d, to form the first memory cell 131. The stacked strip structure 110d serves as the second stacked strip structure corresponding to the row of memory subarray 120d, and each conductive strip 111 in the stacked strip structure 110d serves as the second control gate of each memory-cell group 121 in the row of memory subarray 120d, to form the second memory cell 132.

Generally, in the column direction Y, the stacked strip structure 110 arranged at the first side (i.e., the upper side shown in FIG. 2) of each row of memory subarray 120 serves as the first stacked strip structure corresponding to the corresponding row of memory subarray 120, and each conductive strip 111 therein serves as the first control gate of each memory-cell group 121 in the corresponding row of memory subarray 120, to form the first memory cell 131. The stacked strip structure 110 arranged at the second side (i.e., the lower side shown in FIG. 2) of each row of memory subarray 120 serves as the second stacked strip structure corresponding to the corresponding row of memory subarray 120, and each conductive strip 111 therein serves as the second control gate of each memory-cell group 121 in the corresponding row of memory subarray 120, to form the second memory cell 132.

Therefore, other than the first one and the last one of the stacked strip structures 110, each conductive strip 111 in each stacked strip structure 110 at the non-edge region not only serves as the second control gate of each memory-cell group 121 in the previous row of memory subarray 120, to form the second memory cell 132, but also serves as the first control gate of each memory-cell group 121 in the next row of memory subarray 120, to form the first memory cell 131.

Each first memory cell 131 matches at least part of a corresponding conductive strip 111 in the first stacked strip structure and at least part of a corresponding semiconductor structure 125. Each second memory cell 132 matches at least part of a corresponding conductive strip 111 in the second stacked strip structure and at least part of a corresponding semiconductor structure 125.

Each stacked strip structure 110 at the non-edge region corresponds to two rows of memory subarrays 120. That is, each stacked strip structure 110 at the non-edge region is involved in forming two adjacent rows of memory subarrays 120. In some embodiments. In case that the number of the stacked strip structures 110 in the memory block 100 is regarded as N, N is a positive integer, other than the first one and the Nth one of the stacked strip structures 110, each stacked strip structure 110 at the non-edge region corresponds to two rows of memory subarrays 120. Each conductive strip 111 in each stacked strip structure 110 at the non-edge region serves as the first control gate of the memory-cell groups 121 in one of the two rows of memory subarrays 120, to form the first memory cells 131, and serves as the second control gate of the memory-cell groups 121 in the other of the two rows of memory subarrays 120, to form the second memory cells 132. Each of the first one and the Nth one of the stacked strip structures 110 corresponds to one row of memory subarray 120. The first one of the stacked strip structures 110 is configured to form the first memory cell 131. The Nth one of the stacked strip structures 110 is configured to form the second memory cell 132.

Therefore, other than the first one and the Nth one of the stacked strip structures 110, in each stacked strip structure 110 at the non-edge region, each conductive strip 111 corresponds to two rows of memory subarrays 120, serves as the first control gate of one of the two rows of memory subarrays 120 to form a row of first memory cells 131, and serves as the second control gate of the other of the two rows of memory subarrays 120 to form a row of second memory cells 132. As for the first one and the Nth one of the stacked strip structures 110, each conductive strip therein corresponds to one row of memory subarray 120. Each conductive strip 111 in the first one of the stacked strip structures 110 is configured to form a row of first memory cells 131, and each conductive strip 111 in the Nth one of the stacked strip structures 110 is configured to form a row of second memory cells 132.

For example, in case that the number of the stacked strip structures 110 in the memory block 100 is regarded as N, the number of the rows of memory subarrays 120 may be N−1, and the memory block 100 includes N−1 rows of the memory-cell groups 121. Furthermore, the number of the memory-cell groups 121 in each row of memory subarray is the same as each other, and is regarded as M. The memory block 100 includes M columns of memory-cell groups 121, that is, the memory block 100 includes (N−1)*M memory-cell groups 121 in total. In case that the number of the conductive strips 111 in each stacked strip structure 110 is further regarded as L, each memory-cell group 121 includes 2L memory cells 130. In this way, the memory block 100 includes (N−1)*M*2L memory cells 130 in total. The N, M, and L are positive integers.

The memory block 100 may be configured to apply voltages to a selected memory cell 130 through the various types of connection lines (such as the source lines 141, the bit lines 142, the well-region lines 143, the source control lines 144, the bit-line control lines 145, and so on shown in FIG. 9), and realize different types of memory operations, such as read, program, and erase.

The memory array and various types of the connecting lines included in the memory block 100 will be described in detail in the following.

The multiple rows of memory subarrays 120 in the memory array may be evenly or substantially evenly distributed at predetermined intervals in the column direction. It should be noted that although FIG. 2 only shows five rows of memory subarrays 120a, 120b, 120c, 120d, and 120e, FIG. 2 is only a schematic partial-structure view of a memory block according to an embodiment of the present disclosure, and the present disclosure does not limit the number of the rows of memory subarrays 120.

As shown in FIG. 2, the multiple stacked strip structures 110 in the memory block may be evenly or substantially evenly distributed at predetermined intervals in the column direction. It should be noted that although FIG. 2 only shows four stacked strip structures 110a, 110b, 110c, and 110d, FIG. 2 is only a schematic partial-structure view of a memory block according to an embodiment of the present disclosure, and the present disclosure does not limit the number of the stacked strip structures 110.

Each stacked strip structure 110 includes a plurality of conductive strips 111 and a plurality of insulating strips 112 alternately stacked one by one in the height direction. For example, in case that the conductive strip 111 is regarded as A and the insulating strip 112 is regarded as B, each stacked strip structure 110 may be arranged in a way of BABA A, which is not limited in the present disclosure, and those skilled in the art may make choices according to actual needs. In the height direction, the conductive strips 111 with same distances from the substrate are located on a same layer.

In FIG. 2, each stacked strip structure 110 includes three conductive strips (111a, 111b, and 111c) and three insulating strips 112. That is, the memory array includes three layers of the conductive strips. It should be noted that FIG. 2 is only a schematic partial-structure view of a memory block according to an embodiment of the present disclosure. The present disclosure does not limit the number of the conductive strips 111 and the insulating strips 112 in each stacked strip structure 110, and the conductive strip 111 and the insulating strip 112 may be alternately arranged one by one.

The conductive strip 111 may be made of metals (such as copper, aluminum, tungsten, or their alloys), doped or undoped semiconductor materials (such as polysilicon, polycrystalline germanium, or other suitable materials). In the height direction, a thickness of the conductive strip 111 may be between 40 nm and 160 nm. For example, the thickness of the conductive strip 111 may be 40 nm, 60 nm, 80 nm, 100 nm, 120 nm, 140 nm, and 160 nm. The insulating strip 112 may be made of dielectric materials, such as silicon oxide, silicon nitride, silicon oxynitride, and the like. As shown in FIG. 2, each row of memory subarray 120 may include one or more memory-cell groups 121 and insulating structures 122. While each row of memory subarray 120 includes a plurality of memory-cell groups 121 distributed along the row direction. Each memory-cell group 121 is substantially tube-shaped, and enclosed to form an internal space. The insulating structure 122 includes a first insulating structure 1221 arranged in the internal space of each semiconductor structure 125 and a second insulating structure 1222 that isolates each semiconductor structure 125 from other semiconductor structures 125 in the same row of memory subarray 120.

It should be noted that although each row of memory subarray 120 in FIG. 2 only includes four memory-cell groups 121, FIG. 2 is only a schematic partial-structure view of a memory block according to an embodiment of the present disclosure, and the present disclosure does not limit the number of the memory-cell groups 121 in each row of memory subarray 120.

As shown in FIG. 2, in some embodiments, each semiconductor structure 125 in each row of memory subarray 120 is independent from the others in the row direction. In some embodiments, the second insulating structure 1222 is arranged between any two adjacent semiconductor structures 125, so that each semiconductor structure 125 in each row of memory subarray 120 is independent from the others.

As shown in FIG. 2, in some embodiments, the memory-cell groups 121 in two adjacent rows of memory subarrays 120 are misaligned with each other in the Y direction to save an region occupied by the rows of memory subarrays 120. FIG. 2 shows five rows of memory subarrays 120, and each row of memory subarray 120 includes four memory-cell groups 121 to form four columns of memory-cell groups 121. In FIG. 2, in the first, third and fifth rows, the memory-cell groups 121 located in the same column are aligned with each other. In the second and fourth rows, the memory-cell groups 121 located in the same column are aligned with each other. In the first and second rows, the memory-cell groups 121 located in the same column are misaligned with each other. In the second and third rows, the memory-cell groups 121 located in the same column are misaligned with each other. In the third and fourth rows, the memory-cell groups 121 located in the same column are misaligned with each other. In the fourth and fifth rows, the memory-cell groups 121 located in the same column are misaligned with each other.

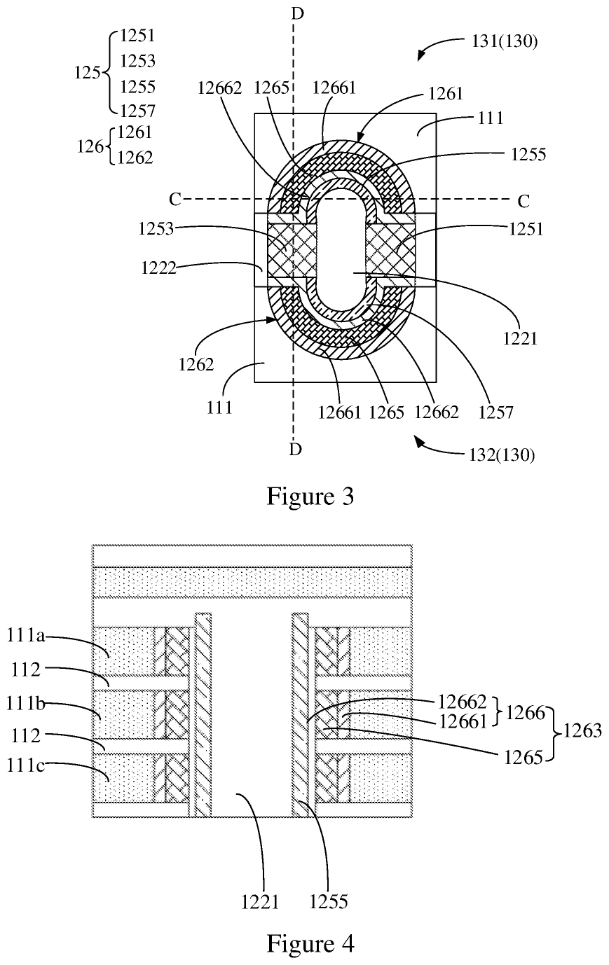

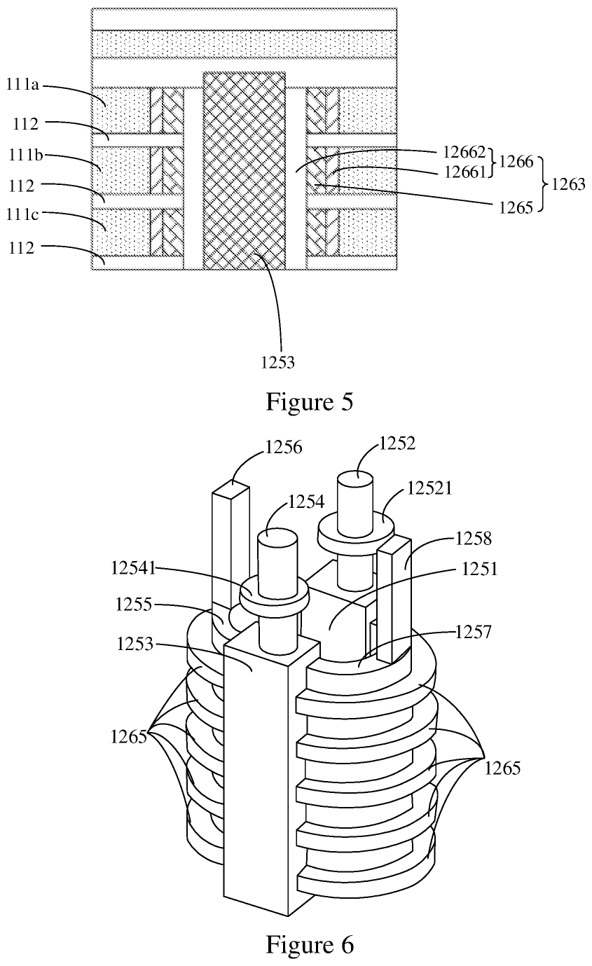

One memory-cell group 121 in the memory block 100 will be described in detail in the following. The other memory-cell groups 121 in the memory block 100 may be the same or substantially the same as the one memory-cell group 121, which will not be repeated herein. As shown in FIGS. 3 to 6, FIG. 3 is a schematic sectional-structure view of a memory-cell group on a plane perpendicular to a height direction in FIG. 2. FIG. 4 is a schematic sectional-structure view of the memory-cell group along C-C in FIG. 3. FIG. 5 is a schematic sectional-structure view of the memory-cell group along D-D in FIG. 3. FIG. 6 is a schematic partial-structure view of the memory-cell group in FIG. 2. FIG. 6 does not show insulating dielectric structures, such as an insulating dielectric layer 1266 that wraps a floating gate 1265.

The memory-cell group 121 corresponds to two stacked strip structures 110. It should be noted that the “two stacked strip structures 110 corresponding to the memory-cell groups 121” mentioned in the present disclosure refers to two stacked strip structures 110 corresponding to the row of memory subarray 120 in which the memory-cell group 121 is located. Similarly, the first stacked strip structure corresponding to the memory-cell group 121 refers to the first stacked strip structure corresponding to the row of memory subarray 120 in which the memory-cell group 121 is located. The second stacked strip structure corresponding to the memory-cell group 121 refers to the second stacked strip structure corresponding to the row of memory subarray 120 in which the memory-cell group 121 is located.

As shown in FIGS. 2, 3 and 6, the memory-cell group 121 may include a semiconductor structure 125 and a memory structure 126. The semiconductor structure 125 extends along the height direction. On a plane perpendicular to the height direction, a cross section of the semiconductor structure 125 is in a shape of a closed ring. It should be noted that the “ring” described in the present disclosure is not limited to a circular ring, but may also include a runway shaped ring as shown in FIG. 2 or a square ring. It can be understood by those skilled in the art that in the present disclosure, components of the semiconductor structure 125 are connected end to end on the cross section, so as to define a closed space on the cross section. In the present disclosure, the cross section of the semiconductor structure 125 is defined to be ring-shaped, however, the components of the semiconductor structure 125 are not limited to have a same size as each other. It merely means that the components of the semiconductor structure 125 are connected end to end on the cross section. In addition, the semiconductor structure 125 extends along the height direction, so that the semiconductor structure 125 is substantially arranged in a tube-like shape. The memory structure 126 is arranged between the semiconductor structure 125 and the two stacked strip structures 110 corresponding to the memory-cell group 121.

As shown in FIGS. 3 and 6, the semiconductor structure 125 includes a source-region semiconductor structure 1251, a drain-region semiconductor structure 1253, a first channel semiconductor structure 1255 arranged between the source-region semiconductor structure 1251 and the drain-region semiconductor structure 1253, and a second channel semiconductor structure 1257 arranged between the source-region semiconductor structure 1251 and the drain-region semiconductor structure 1253.

The source-region semiconductor structure 1251, the drain-region semiconductor structure 1253, the first channel semiconductor structure 1255, and the second channel semiconductor structure 1257 extend along the height direction respectively. The source-region semiconductor structure 1251 and the drain-region semiconductor structure 1253 are spaced apart from each other along the row direction. The first channel semiconductor structure 1255 is located on one side of the source-region semiconductor structure 1251 and the drain-region semiconductor structure 1253, and connects the source-region semiconductor structure 1251 to the drain-region semiconductor structure 1253. The second channel semiconductor structure 1257 is located on the other side of the source-region semiconductor structure 1251 and the drain-region semiconductor structure 1253, and connects the source-region semiconductor structure 1251 to the drain-region semiconductor structure 1253.

Cross sections of the first channel semiconductor structure 1255 and the second channel semiconductor structure 1257 on the plane perpendicular to the height direction may be arc-shaped respectively, and bent in directions away from each other, respectively. In this way, the semiconductor structure 125 is tube-shaped as a whole. In some embodiments, on the plane perpendicular to the height direction, the cross sections of the first channel semiconductor structure 1255 and the second channel semiconductor structure 1257 may also be in a fold-line shape, which is not limited in the present disclosure, and those skilled in the art may make choices according to actual needs.

The source-region semiconductor structure 1251 and the drain-region semiconductor structure 1253 are semiconductor structures of a first doping type. The first channel semiconductor structure 1255 and the second channel semiconductor structure 1257 are semiconductor structures of a second doping type. In some embodiments, the source-region semiconductor structure 1251 and the drain-region semiconductor structure 1253 may be made of N-type doped polysilicon. The first channel semiconductor structure 1255 and the second channel semiconductor structure 1257 may be made of P-type doped polysilicon. In some embodiments, the source-region semiconductor structure 1251 and the drain-region semiconductor structure 1253 may be made of the P-type doped polysilicon. The first channel semiconductor structure 1255 and the second channel semiconductor structure 1257 may be made of the N-type doped polysilicon, which is not limited in the present disclosure, and those skilled in the art may make choices according to actual needs.

In the present disclosure, on the plane perpendicular to the height direction, the cross sections of the first channel semiconductor structure 1255 and the second channel semiconductor structure 1257 are arc-shaped. In this way, a channel length is extended, and the device performance is improved.

As shown in FIGS. 2 and 3, the memory structure 126 includes an arc-shaped first memory structure 1261 and an arc-shaped second memory structure 1262. The first memory structure 1261 is arranged between the first stacked strip structure and the source-region semiconductor structure 1251, the drain-region semiconductor structure 1253, and the first channel semiconductor structure 1255. A bending direction of the first memory structure 1261 is the same as a bending direction of the first channel semiconductor structure 1255. In some embodiments, the first memory structure 1261 may also be in a fold-line shape. The bending direction of the first memory structure 1261 is the same as the bending direction of the first channel semiconductor structure 1255, which is not limited in the present disclosure, and those skilled in the art may make choices according to actual needs.

The second memory structure 1262 is arranged between the second stacked strip structure and the source-region semiconductor structure 1251, the drain-region semiconductor structure 1253, and the second channel semiconductor structure 1257. A bending direction of the second memory structure 1262 is the same as a bending direction of the second channel semiconductor structure 1257. In some embodiments, the second memory structure 1262 may also be in a fold-line shape. The bending direction of the second memory structure 1262 is the same as the bending direction of the second channel semiconductor structure 1257, which is not limited in the present disclosure, and those skilled in the art may make choices according to actual needs.

In some embodiments, each of the first memory structure 1261 and the second memory structure 1262 may include a plurality of floating-gate memory structures 1263 distributed along the height direction. In some embodiments, the number of the floating-gate memory structures 1263 in the first memory structure 1261 may be the same as the number of the conductive strips 111 in the first stacked strip structure. The number of the floating-gate memory structures 1263 in the second memory structure 1262 may be the same as the number of the conductive strips 111 in the second stacked strip structure. Each floating-gate memory structure 1263 is involved in forming one memory cell 130.

Each conductive strip 111 in the first stacked strip structure and the second stacked strip structure serves as the control gate of the memory-cell group 121, to form the memory cell 130. Each conductive strip 111 in the first stacked strip structure serves as the first control gate of the memory-cell group 121, to form the first memory cell 131. Each conductive strip 111 in the second stacked strip structure serves as the second control gate of the memory-cell group 121, to form the second memory cell 132.

For example, in case that the number of the conductive strips 111 in each stacked strip structure 110 is regarded as L, the conductive strips 111 in the first stacked strip structure serve as first control gates of the memory-cell group 121, and are involved in forming L first memory cells 131. Each first memory cell 131 includes one floating-gate memory structure 1263. That is, the first memory structure 1261 includes L floating-gate memory structures 1263 distributed along the height direction. The conductive strips 111 in the second stacked strip structure serve as second control gates of the memory-cell group 121, and are involved in forming L second memory cells 132. Each second memory cell 132 includes one floating-gate memory structure 1263. That is, the second memory structure 1262 includes L floating-gate memory structures distributed along the height direction.

As shown in FIG. 3, each first memory cell 131 matches at least part of the corresponding conductive strip 111, the first channel semiconductor structure 1255, the source-region semiconductor structure 1251, and the drain-region semiconductor structure 1253. At least part of the corresponding conductive strip 111 serves as the control gate of the first memory cell 131. In addition, each first memory cell 131 also includes one floating-gate memory structure 1263.

In each first memory cell 131, projections of the control gate and the first channel semiconductor structure 1255 on a projection plane are overlapped, and the projection plane is perpendicular to the column direction. The floating-gate memory structure 1263 is arranged between the control gate and the first channel semiconductor structure 1255. It should be noted that, in the absence of special instructions, the “overlapped” described in the present disclosure refers to “at least partially overlapped”.

Each second memory cell 132 matches at least part of the corresponding conductive strip 111, the second channel semiconductor structure 1257, the source-region semiconductor structure 1251, and the drain-region semiconductor structure 1253. At least part of the corresponding conductive strip 111 serves as the control gate of the second memory cell 132. In addition, each second memory cell 132 also includes one floating-gate memory structures 1263.

In each second memory cell 132, projections of the control gate and the second channel semiconductor structure 1257 on the projection plane are overlapped, and the projection plane is perpendicular to the column direction. The floating-gate memory structure 1263 is arranged between the control gate and the second channel semiconductor structure 1257. It should be noted that, in the absence of special instructions, the “overlapped” described in the present disclosure refers to “at least partially overlapped”.

The floating-gate memory structure 1263 includes a floating gate 1265 and an insulating dielectric layer 1266 wrapping the floating gate 1265. In each memory cell 130, the floating-gate memory structure 1263 is arranged between the control gate and the first/second channel semiconductor structure 1255/1257, and any surface of the floating gate 1265 is wrapped by the insulating dielectric layer 1266. The first/second channel semiconductor structure represents the first channel semiconductor structure 1255 or the second channel semiconductor structure 1257. In case that the corresponding memory cell is the first memory cell 131, the first/second channel semiconductor structure is the first channel semiconductor structure 1255. In case that the corresponding memory cell is the second memory cell 132, the first/second channel semiconductor structure is the second channel semiconductor structure 1257.

As shown in FIGS. 3 to 6 (the insulating dielectric structures are not shown in FIG. 6, such as the insulating dielectric layer 1266 wrapping the floating gate 1265), since the floating gate 1265 is wrapped by the insulating dielectric layer 1266, a plurality of floating gates 1265 in the first memory structure 1261 and the second memory structure 1262 are spaced apart from each other. That is, in the memory-cell group 121, different floating gates in different memory cells are spaced apart from each other. The floating gate 1265 may be made of doped polysilicon materials, which is not limited in the present disclosure, and those skilled in the art may make choices according to actual needs.

The floating-gate memory structure 1263, which using polysilicon as the floating gate 1265, is characterized by that injected charges may not only move in an injection/removal direction, but also move arbitrarily in the floating gate 1265. In the memory block 100 adopting the floating-gate memory structure 1263, in case that the floating gate 1265 is a continuous structure, the charges may move arbitrarily along an extending direction of the floating gate 1265. That is, the charges may move between the memory cells 130, and memory operations for one specific memory cell 130 cannot be realized. Therefore, for the memory block 100 adopting the floating-gate memory structure 1263, the adjacent floating gates 1265 should be independent from each other, so as to avoid the charges moving between the memory cells 130 and facilitate the memory operations for the specific memory cell 130.

As shown in FIGS. 3 to 5, the insulating dielectric layer 1266 wrapping the floating gate 1265 may include a first dielectric layer 12661 arranged between the floating gate 1265 and the conductive strip 111, a second dielectric layer 12662 arranged between the floating gate 1265 and the source-region semiconductor structure 1251, the drain-region semiconductor structure 1253, and the first/second channel semiconductor structure 1255/1257, and an insulating strip 112 configured to isolate two adjacent floating gates 1265 in the height direction. The first dielectric layer 12661, the floating gate 1265, and the second dielectric layer 12662 are sequentially stacked. The first dielectric layer 12661 and the second dielectric layer 12662 may be made of dielectric materials, such as silicon oxide, silicon nitride, silicon oxynitride, etc., which is not limited in the present disclosure, and those skilled in the art may make choices according to actual needs.

It should be noted that, as shown in FIG. 3, the second insulating structure 1222 and the second dielectric layer 12662 may be made of the same materials, which is not limited in the present disclosure, and those skilled in the art may make choices according to actual needs.

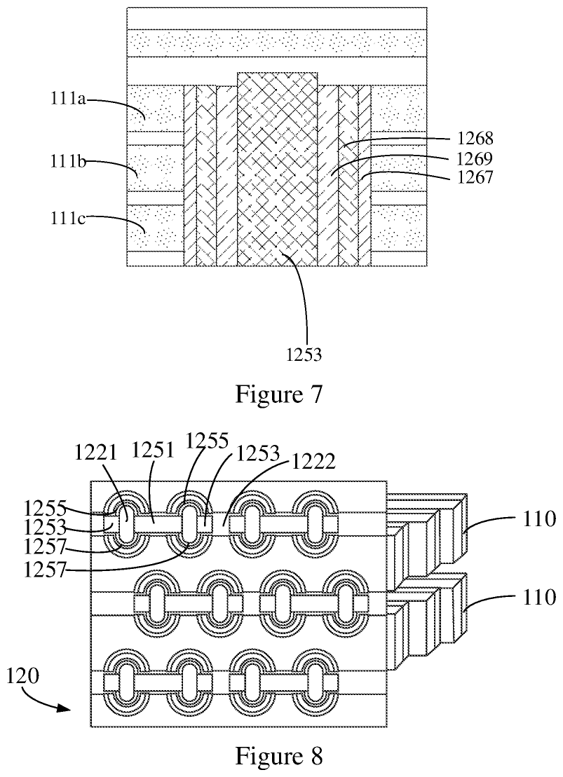

In some embodiments, as shown in FIG. 7, FIG. 7 is a schematic sectional-structure view of the memory-cell group of the memory block along D-D (D-D represents a plane perpendicular to the row direction) according to a further embodiment of the present disclosure. The first memory structure 1261 and the second memory structure 1262 may be charge-trapping memory structures respectively, and extend along the height direction respectively.

In some embodiments, the charge-trapping memory structure includes a first dielectric layer 1267, a charge-trapping layer 1268 and a second dielectric layer 1269. The first dielectric layer 1267, the charge-trapping layer 1268 and the second dielectric layer 1269 extend along the height direction respectively. As for the first memory structure 1261, the first dielectric layer 1267 is arranged between the charge-trapping layer 1268 and the first stacked strip structure. The charge-trapping layer 1268 is arranged between the first dielectric layer 1267 and the second dielectric layer 1269. The second dielectric layer 1269 is arranged between the charge-trapping layer 1268 and the source-region semiconductor structure 1251, the drain-region semiconductor structure 1253, and the first channel semiconductor structure 1255. In other words, the first dielectric layer 1267, the charge-trapping layer 1268, and the second dielectric layer 1269 are sequentially stacked.

For the second memory structure 1262, the first dielectric layer 1267 is arranged between the charge-trapping layer 1268 and the second stacked strip structure. The charge-trapping layer 1268 is arranged between the first dielectric layer 1267 and the second dielectric layer 1269. The second dielectric layer 1269 is arranged between the charge-trapping layer 1268 and the source-region semiconductor structure 1251, the drain-region semiconductor structure 1253, and the second channel semiconductor structure 1257. In other words, the first dielectric layer 1267, the charge-trapping layer 1268, and the second dielectric layer 1269 are sequentially stacked.

In some embodiments, each first memory cell 131 matches at least part of the corresponding conductive strip 111, the first channel semiconductor structure 1255, the source-region semiconductor structure 1251, the drain-region semiconductor structure 1253, and at least part of the first memory structure 1261. At least part of the corresponding conductive strip 111 serves as the control gate of the first memory cell 131.

In each first memory cell 131, projections of the control gate and the first channel semiconductor structure 1255 on the projection plane are overlapped, and the projection plane is perpendicular to the column direction. The first memory structure 1261 is arranged between the conductive strip 111 and the first channel semiconductor structure 1255. It should be noted that, in the absence of special instructions, the “overlapped” described in the present disclosure refers to “at least partially overlapped”.

Each second memory cell 132 matches at least part of the corresponding conductive strip 111, the second channel semiconductor structure 1257, the source-region semiconductor structure 1251, the drain-region semiconductor structure 1253, and at least part of the second memory structure 1262. At least part of the corresponding conductive strip 111 serves as the control gate of the second memory cell 132.

In each second memory cell 132, projections of the control gate and the second channel semiconductor structure 1257 on a projection plane are overlapped, and the projection plane is perpendicular to the column direction. The second memory structure 1262 is arranged between the conductive strip 111 and the second channel semiconductor structure 1257. It should be noted that, in the absence of special instructions, the “overlapped” described in the present disclosure refers to “at least partially overlapped”.

The charge-trapping layer 1268 may be made of memory materials with charge-trapping characteristics. For example, the charge-trapping layer 1268 may be made of silicon nitride, which is not limited in the present disclosure, and those skilled in the art may make choices according to actual needs.

A difference between the charge-trapping memory structure and the floating-gate memory structure 1263 is that, in the charge-trapping memory structure, injected charges are fixed close to an injection point and may only move in an injection/removal direction. That is, the memory charges may only be fixed close to the injection point and cannot move arbitrarily in the charge-trapping layer 1268, especially cannot move in the extending direction of the charge-trapping layer 1268 (i.e., the height direction). Therefore, even if the charge-trapping layer 1268 is arranged from top to bottom in the height direction, the charges will not move between the memory cells 130.

The first dielectric layer 1267 and the second dielectric layer 1269 in the charge-trapping memory structure may be made of dielectric materials, such as silicon oxide, silicon oxynitride, etc., which is not limited in the present disclosure, and those skilled in the art may make choices according to actual needs. In some embodiments, the first memory structure 1261 and the second memory structure 1262 may also be other types of capacitive dielectric structures, which is not limited in the present disclosure, and those skilled in the art may make choices according to actual needs.

The memory-cell group 121 is described in detail above. As aforementioned, each row of memory subarray 120 may include the memory-cell groups 121 and the insulating structures 122. The insulating structures 122 will be described in detail in the following.

As shown in FIG. 2, the insulating structures 122 include first insulating structures 1221 and second insulating structures 1222. The first insulating structures 1221 and the second insulating structures 1222 may be made of dielectric materials, such as silicon oxide, silicon nitride, silicon oxynitride, and so on, which is not limited in the present disclosure, and those skilled in the art may make choices according to actual needs. The first insulating structure 1221 is arranged in the internal space formed by the source-region semiconductor structure 1251, the drain-region semiconductor structure 1253, the first channel semiconductor structure 1255, and the second channel semiconductor structure 1257 in each memory-cell group 121 cooperatively.

In the embodiment shown in FIG. 2, each semiconductor structure 125 in each row of memory subarray 120 is independent from the others. The second insulating structure 1222 is arranged between any two adjacent semiconductor structures 125. For example, in the row direction, each memory-cell group 121 may include the source-region semiconductor structure 1251, the first channel semiconductor structure 1255 and the second channel semiconductor structure 1257, and the drain-region semiconductor structure 1253. For example, the second insulating structure 1222 may be arranged between the drain-region semiconductor structure 1253 of each memory-cell group 121 and the source-region semiconductor structure 1251 of an adjacent memory-cell group 121, or between the source-region semiconductor structure 1251 of each memory-cell group 121 and the drain-region semiconductor structure 1253 of the adjacent memory-cell group 121.

As shown in FIG. 8, FIG. 8 is a schematic partial-structure view of the memory block according to a further embodiment of the present disclosure. In some embodiments, every two adjacent semiconductor structures 125 in each row of memory subarray 120 are independent from the others. That is, two adjacent memory-cell groups 121 share the same source-region semiconductor structure 1251.

As shown in FIG. 8, in the row direction, two adjacent memory-cell groups 121 include the drain-region semiconductor structure 1253, the first channel semiconductor structure 1255 and the second channel semiconductor structure 1257, the source-region semiconductor structure 1251, the first channel semiconductor structure 1255 and the second channel semiconductor structure 1257, and the drain-region semiconductor structure 1253, so as to share the same source-region semiconductor structure 1251. The second insulating structure 1222 is arranged between the drain-region semiconductor structure 1253 in every two adjacent memory-cell groups 121 and the drain-region semiconductor structure 1253 in another two adjacent memory-cell groups 121 adjacent to the every two adjacent memory-cell groups 121.

In some embodiments, the memory-cell groups 121 in two adjacent rows of memory subarrays 120 are aligned with each other. That is, the memory-cell groups 121 located in the same column are aligned with each other. As shown in FIG. 9, FIG. 9 is a schematic partial-structure view of the memory block according to a further embodiment of the present disclosure. In FIG. 9, the X direction is the row direction, the Y direction is the column direction, and the Z direction is the height direction. Three rows of memory subarrays 120 are shown in FIG. 9. Each row of memory subarray 120 includes three memory-cell groups 121, and three columns of memory-cell groups 121 are formed. The memory-cell groups 121 located in the same column are aligned with each other.

It should be noted that the difference between the embodiment described in FIG. 2 and the embodiment described in FIG. 9 is only that the memory-cell groups 121 in two adjacent rows of memory subarrays 120 is aligned or misaligned with each other. Other features may be the same as or similar to each other. For example, arrangement of various types of the connecting lines in FIG. 9 described below may also be applied to the embodiment shown in FIG. 2.

The memory array in the memory block 100 has been described in detail as above. Various types of the connecting lines included in the memory block 100 will be described in the following.

As shown in FIG. 9, various types of connection lines in the memory block 100 include the word lines, the source lines 141, the bit lines 142, the well-region lines 143, the source control lines 144, and the bit-line control lines 145.

As shown in FIGS. 2 and 9, each conductive strip 111 in each stacked strip structure 110 may serves as one word line. That is, the word line extends along the row direction. For example, in case that the number of the conductive strips 111 in each stacked strip structure 110 is regarded as L, and the number of the stacked strip structures 110 in the memory block 100 is regarded as N, the memory block 100 includes L*N conductive strips 111 in total. Each conductive strip 111 may serve as one word line, that is, the memory block 100 includes L*N word lines in total. Odd ones of the conductive strips 111 in the same layer are connected together, and even ones of the conductive strips 111 in the same layer are connected together.

As shown in FIG. 6, the semiconductor structure 125 in the memory-cell group 121 further includes a source-region-semiconductor connecting column 1252 connected to the source-region semiconductor structure 1251 in the height direction and extending along the height direction, a drain-region-semiconductor connecting column 1254 connected to the drain-region semiconductor structure 1253 in the height direction and extending along the height direction, the first channel-semiconductor connecting column 1256 connected to the first channel semiconductor structure 1255 in the height direction and extending along the height direction, and the second channel-semiconductor connecting column 1258 connected to the second channel semiconductor structure 1257 in the height direction and extending along the height direction.

The material of the source-region-semiconductor connecting column 1252 may be the same as or similar to the material of the source-region semiconductor structure 1251. The material of the drain-region-semiconductor connecting column 1254 may be the same as or similar to the material of the drain-region semiconductor structure 1253. The material of the first channel-semiconductor connecting column 1256 may be the same as or similar to the material of the first channel semiconductor structure 1255. The material of the second channel-semiconductor connecting column 1258 may be the same as or similar to the material of the second channel semiconductor structure 1257, which is easy for those skilled in the art to understand, and will not be repeated herein.

As shown in FIGS. 6 and 9, source-region semiconductor structures 1251 of a plurality of memory-cell groups 121 in the same row are connected to the same source line 141 through corresponding source-region-semiconductor connecting columns 1252. That is, the source line 141 extends along the row direction. In case that the number of the stacked strip structures 110 in the memory block 100 is regarded as N, the number of the rows of memory subarrays 120 may be N−1. Each row of memory-cell groups 121 corresponds to one source line 141. The memory block 100 includes N−1 source pole lines 141 in total.

It should be noted that although only two source lines 141-1 and 141-2 are shown in FIG. 9, FIG. 9 is only a schematic partial-structure view of a memory block according to an embodiment of the present disclosure. The present disclosure does not limit the number of the source lines 141, and those skilled in the art may make choices according to actual needs.

As shown in FIGS. 6 and 9, drain-region semiconductor structures 1253 of a plurality of memory-cell groups 121 in the same column are connected to the same bit line 142 through corresponding drain-region-semiconductor connecting columns 1254. That is, the bit line 142 extends along the column direction. For example, in case that the number of memory-cell groups 121 in each row of memory subarray is regarded as M, the memory block 100 includes M columns of memory-cell groups 121 in total. Each column of memory-cell groups 121 corresponds to one bit line 142. The memory block 100 includes M bit lines 142 in total.

It should be noted that although only two bit lines 142-1 and 142-2 are shown in FIG. 9, FIG. 9 is only a schematic partial-structure view of a memory block according to an embodiment of the present disclosure. The present disclosure does not limit the number of the bit lines 142, and those skilled in the art may make choices according to actual needs.

As shown in FIGS. 6 and 9, first channel semiconductor structures 1255 and second channel semiconductor structures 1257 of the memory-cell groups 121 in the same column are connected to the same well-region line 143 through corresponding first channel-semiconductor connecting columns 1256 and corresponding second channel-semiconductor connecting columns 1258. That is, the well-region line 143 extends along the column direction. For example, in case that the number of the memory-cell groups 121 in each row of memory subarray is regarded as M, the memory block 100 includes M columns of memory-cell groups 121 in total. Each column of memory-cell groups 121 corresponds to one well-region line 143. The memory block 100 includes M well-region line 143 in total.

All well-region lines 143 of the memory block 100 may be connected together. It should be noted that although only two well-region lines 143-1 and 143-2 are shown in FIG. 9, FIG. 9 is only a schematic partial-structure view of a memory block according to an embodiment of the present disclosure. The present disclosure does not limit the number of the well-region lines 143, and those skilled in the art may make choices according to actual needs.

As shown in FIGS. 6 and 9, the source-region-semiconductor connecting column 1252 in each memory-cell group 121 is further sleeved with a source-region conductive controlling ring 12521. Source-region conductive controlling rings 12521 of the memory-cell groups 121 in the same column are connected to the same source controlling line 144. That is, the source controlling line 144 extends along the column direction. For example, in case that the number of memory-cell groups 121 in each row of memory subarray is regarded as M, the memory block 100 includes M columns of memory-cell groups 121 in total. Each column of memory-cell groups 121 corresponds to one source controlling line 144. The memory block 100 includes M source controlling lines 144 in total.

It should be noted that although only two source controlling lines 144-1 and 144-2 are shown in FIG. 9, FIG. 9 is only a schematic partial-structure view of a memory block according to an embodiment of the present disclosure. The present disclosure does not limit the number of the source controlling lines 144, and those skilled in the art may make choices according to actual needs.

The source-region conductive controlling ring 12521 may be made of conductive materials, such as doped silicon or metal. In case that a source controlling voltage is applied to the source-region conductive controlling ring 12521 via the source controlling line 144, a corresponding part of the source-region-semiconductor connecting column 1252 is inverted, for example, from one doping type to the other. In this way, voltages or current signals may be isolated.

As shown in FIGS. 6 and 9, the drain-region-semiconductor connecting column 1254 in each memory-cell group 121 is further sleeved with a drain-region conductive controlling ring 12541. Drain-region conductive controlling rings 12541 of the memory-cell groups 121 in the same column are connected to the same bit-line controlling line 145. That is, the bit-line controlling line 145 extends along the column direction. For example, in case that the number of memory-cell groups 121 in each row of memory subarray is regarded as M, the memory block 100 includes M columns of memory-cell groups 121 in total. Each column of memory-cell groups 121 corresponds to one bit-line controlling line 145. The memory block 100 includes M bit-line controlling lines 145 in total.

It should be noted that although only two bit-line controlling lines 145-1 and 145-2 are shown in FIG. 9, FIG. 9 is only a schematic partial-structure view of a memory block according to an embodiment of the present disclosure. The present disclosure does not limit the number of the bit-line controlling lines, and those skilled in the art may make choices according to actual needs.

The drain-region conductive controlling ring 12541 may be made of conductive materials, such as doped silicon or metal. In case that a bit-line controlling voltage is applied to the drain-region conductive controlling ring 12541 via the bit-line controlling line 145, a corresponding part of the drain-region-semiconductor connecting column 1254 is inverted, for example, from one doping type to the other. In this way, voltages or current signals may be isolated.

In the present disclosure, the source-region-semiconductor connecting column 1252 in each memory-cell group 121 is further sleeved with the source-region conductive controlling ring 12521. The source-region conductive controlling rings 12521 of the memory-cell groups 121 in the same column are connected to the same source controlling line 144. The drain-region-semiconductor connecting column 1254 in each memory-cell group 121 is further sleeved with the drain-region conductive controlling ring 12541. The drain-region conductive controlling rings 12541 of the memory-cell groups 121 in the same column are connected to the same bit-line controlling line 145. In this way, the memory block 100 may execute the read operation on one specific memory cell 130 (i.e., read by bit) or execute the programming operation on one specific memory cell 130 (i.e., PGM by bit).

The way of the memory block 100 executing the read operation and the programming operation on one specific memory cell, and the way of the memory block 100 executing the erasing operation will be described in detail in the following.

In case that the memory block 100 needs to select one memory cell 130 to execute the read operation (for the convenience of description, the selected memory cell 130 may be regarded as a target cell), the memory block 100 may be configured to select all the odd or even ones of the conductive strips 111 in one layer (that is, a half of the conductive strips 111 in one layer is selected) to apply a first word-line selecting voltage and execute a layer selection. Through the layer selection, the layer in which the target cell is located may be selected. The first word-line selecting voltage may be a positive voltage, such as 5V. The other unselected conductive strips 111 may be connected to 0V.

The memory block 100 may also be configured to select one bit line 142 (such as 142-1) to apply a first bit-line selecting voltage and execute a column selection. Through the column selection, the column in which the target cell is located may be selected. The first bit-line selecting voltage may be a positive voltage, such as 1V. The other unselected bit lines 142 (such as 142-2) may be connected to 0V.

The memory block 100 may also be configured to select one source line 141 (such as 141-1) to apply a first source selecting voltage and execute a row selection. Through the row selection, the row in which the target cell is located may be selected, so as to select the target cell to execute the read operation in coordination with the layer selection and the column selection. The first source selecting voltage may be 0V. The other unselected source lines 141 (such as 141-2) may be floating.

In addition, in case that the reading operation is executed on the target cell, all the well-region lines 143, all the source controlling lines 144, and all the bit-line controlling lines 145 may be floating. As shown in FIG. 10, FIG. 10 is a schematic structural view of a memory cell in response to the memory cell being executed a reading operation according to the embodiment shown in FIG. 9. In case that electrons are stored in the floating gate 1265 of the target cell, a threshold voltage of the target cell rises. The conductive strip 111 in the target cell serves as the control gate, and receives the first word-line selecting voltage of 5V. The first word-line selecting voltage is not enough to conduct the target cell, that is, no conductive channel exists between the source-region semiconductor structure 1251 and the drain-region semiconductor structure 1253. Therefore, no current exists between the source-region semiconductor structure 1251 and the drain-region semiconductor structure 1253, and “0” is read.

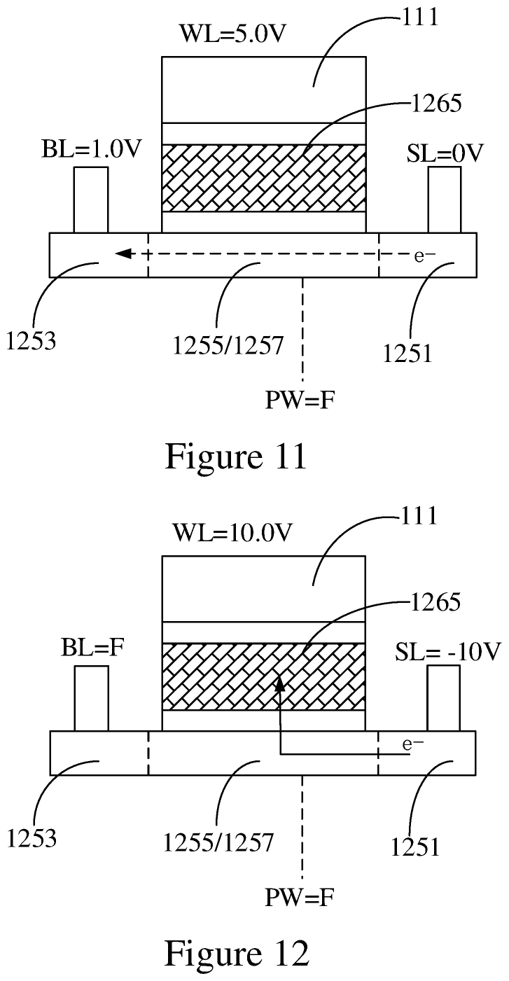

As shown in FIG. 11, FIG. 11 is a further schematic structural view of the memory cell in response to the memory cell being executed the reading operation according to the embodiment shown in FIG. 9. In case that no electrons are stored in the floating gate 1265 of the target cell, and the conductive strip 111 in the target cell serves as the control gate and receives the first word-line selecting voltage of 5V, the first word-line selecting voltage is sufficient to conduct the target cell. That is, a conductive channel exists between the source-region semiconductor structure 1251 and the drain-region semiconductor structure 1253. A current is generated between the source-region semiconductor structure 1251 and the drain-region semiconductor structure 1253, and “1” is read.

In case that the memory block 100 needs to select one memory cell 130 (for the convenience of description, the selected memory cell 130 may be regarded as the target cell) to execute the programming operation, the memory block 100 may be configured to select all the odd or even ones of the conductive strips 111 in one layer (that is, a half of the conductive strips 111 in one layer is selected) to apply a second word-line selecting voltage and execute the layer selection. Through the layer selection, the layer in which the target cell is located may be selected. The second word-line selecting voltage may be a positive voltage, such as 10V. The other unselected conductive strips 111 may be connected to 0V or floating.

The memory block 100 may also be configured to select one source line 141 (such as 141-1) to apply a second source selecting voltage and execute the row selection. Through the row selection, the row in which the target cell is located may be selected. The second source selecting voltage may be a negative voltage, such as −10V. The other unselected source lines 141 (such as 141-2) may be floating or connected to 0V.

The memory block 100 may also be configured to select one source controlling line 144 (such as 144-1), apply no source controlling voltage to the selected source controlling line 144, and apply the source controlling voltage to the other source controlling lines 144 (such as 144-2). The source controlling voltage may be −13V. By applying no source controlling voltage to the column in which the target cell is located, and applying the source controlling voltage to the other columns, the column in which the target cell is located may be selected.

The memory block 100 may also be configured to select one bit-line controlling line 145 (such as 145-1) to apply a bit-line controlling voltage, such as −13V. The selected bit-line controlling line 145-1 and the selected source controlling line 144-1 (that is, the source controlling line on which no source controlling voltage is applied) are connected to a same column of memory-cell groups 121. In this way, the drain-region-semiconductor connecting column 1254 of the memory-cell group 121 in which the target cell is located (for example, the memory-cell group 121 located in a dotted line box in FIG. 9) is turned off to avoid a potential of the bit line 142-1 being pulled to the same as a potential of the selected source line 141-1. It should be noted that in the embodiments that no drain-region conductive controlling ring 12541 is arranged, the potential of the source line 141-1 will be transferred to the bit line 142-1, causing other memory cells 130 in the same column to be programmed.

In addition, in case that the programming operation is executed on the target cell, all well-region lines 143 may be floating, and all bit lines 142 may be floating. As shown in FIG. 12, FIG. 12 is a schematic structural view of the memory cell in response to the memory cell being executed a programming operation according to the embodiment shown in FIG. 9. The source in the target cell receives the second source selecting voltage of −10V. The drain is floating. Electrons flow from the source-region semiconductor structure 1251 to the drain-region semiconductor structure 1253. In a process of flowing from the source-region semiconductor structure 1251 to the drain-region semiconductor structure 1253, the electrons need to pass through under the control gate (i.e., the conductive strip 111). Due to strong positive electric field applied on the control gate, some electrons are “pulled” into the floating gate 1265 of the target cell. Once pulled in, the electrons will no longer have the energy required to escape, so that data is programmed in the target cell, that is, the data is programmed in the target cell by hot carrier injection.

In case that the memory block 100 is configured to execute the erasing operation, the memory block 100 may be configured to select all the odd one of the conductive strips 111 in each layer (that is, a half of the conductive strips 111 in the memory block 100 is selected) to apply a third word-line selecting voltage. The third word-line selecting voltage may be a negative voltage, such as −10V. All the even ones of the conductive strips 111 in each layer may be floating or connected to 0V. All well-region lines 143 of the memory block 100 are connected together. Therefore, by further applying an erasing voltage to all well-region lines 143 of the memory block 100, the erasing operation may be executed on the memory cells 130 formed with a participation of all the odd ones of the conductive strips 111 in each layer (i.e., a half of the memory cells 130 in the memory block 100). The erasing voltage may be a positive voltage, such as 10V.

In some embodiments, in case that the erasing operation is executed on the memory block 100, the memory block 100 may also be configured to select all the even ones of the conductive strips 111 in each layer to apply the third word-line selecting voltage. All the odd ones of the conductive strips 111 in each layer may be floating or connected to 0V. By further applying the erasing voltage to all well-region lines 143 of the memory block 100, the erasing operation may be executed on the memory cells 130 formed with a participation of all the even ones of the conductive strips 111 in each layer. The erasing voltage may be a positive voltage, such as 10V.

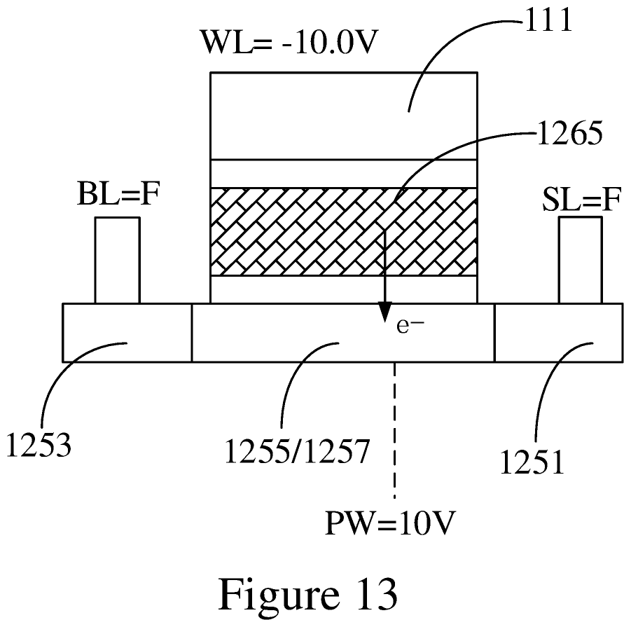

In addition, in case that the erasing operation is executed, all the source lines 141, all the bit lines 142, all the source controlling lines 144, and all the bit-line controlling lines 145 may be floating. As shown in FIG. 13, FIG. 13 is a schematic structural view of the memory cell in response to the memory cell being executed an erasing operation according the embodiment shown in FIG. 9. The first/second channel semiconductor structure 1255/1257 in the target cell receives the erasing voltage of 10V, and the conductive strip 111 serves as the control gate and receives the third word-line selecting voltage of −10V, a strong electric field is generated between the first/second channel semiconductor structure 1255/1257 and the conductive strip 111. In this way, the electrons move from the conductive strip 111 to the first/second channel semiconductor structure 1255/1257, that is, the electrons move from top to bottom, so that the electrons in the floating gate 1265 of the target cell are removed in a way of F-N tunnel effect, and the erasing operation is realized.

It should be noted that various types of the connecting lines included in the memory block 100 and the rows of memory subarrays 120 may be arranged on a same chip, or arranged on two chips respectively. For example, various types of the connecting lines other than the word lines may be arranged on one chip, and the one chip may be stacked on another chip in which the rows of memory subarrays 120 are located by using a 3D bonding technology. The present disclosure does not limit a connection way between the two chips, and those skilled in the art may make choices according to actual needs.

In the present disclosure, the memory block 100 includes a memory array. The memory array includes a plurality of stacked strip structures 110 and a plurality of semiconductor structures 125. The stacked strip structures 110 are spaced apart from each other along the column direction. Each of the stacked strip structures 110 extends along the row direction, and includes a plurality of insulating strips 112 and a plurality of conductive strips 111 alternately stacked along the height direction. Some of the semiconductor structures 125 are arranged between every two of the stacked strip structures 110 adjacent to each other. The every two of the stacked strip structures 110 adjacent to each other and the some of the semiconductor structures 125 arranged therebetween are involved in forming a row of memory subarray 120. Each of the conductive strips 111 in the every two of the stacked strip structures 110 adjacent to each other serves as a control gate of the row of memory subarray 120. Each row of memory subarray 120 includes a plurality of memory-cell groups 121 distributed along the row direction. Each of the memory-cell groups 121 includes a semiconductor structure 125. Each of the semiconductor structures extends along the height direction. The present disclosure provides a three-dimensional stacked structure, and a memory density of memory block 100 is improved. Furthermore, on the plane perpendicular to the height direction, the cross section of each of the semiconductor structures 125 is ring-shaped, so as to improve the performance of the device.

In the above description of the present disclosure, unless otherwise specified and limited, the terms “fixed”, “installed”, “linked”, or “connected” should be understood broadly. For example, the term “connected” may be a fixed connection, a detachable connection, or an integrated structure, may be a mechanical connection or an electrical connection, may be a direct connection or an indirect connection through an intermediate media, or may be an internal connection between two components or an interaction between two components. Therefore, unless otherwise explicitly defined in the present disclosure, those skilled in the art may understand the specific meaning of the above terms in the present disclosure according to specific situations.

According to the above description of the present disclosure, those skilled in the art may also understand that the following terms, such as “up”, “down”, “front”, “back”, “left”, “right”, “length”, “width”, “thickness”, “vertical”, “horizontal”, “top”, “bottom”, “inside”, “outside”, “axial”, “radial”, “circumferential”, “center”, “longitudinal”, “transverse”, “clockwise” or “anticlockwise” indicating an orientation or a position relationship are based on the orientation or the position relationship shown in the figures of the present disclosure, which is only for the purpose of explaining the scheme of the present disclosure and simplifying the present disclosure, rather than indicating or implying that the device or element involved must have a specific orientation, and must be configured and operated in the specific orientation, so that the aforementioned terms indicating an orientation or a position relationship cannot be understood or interpreted as a limitation to the scheme of the present disclosure.

In addition, the terms “first” or “second” used in the present disclosure referring to the number or ordinal number are only for description purposes, and cannot be understood as indicating or implying a relative importance or implying the number of the indicated technical features. Therefore, features defined by the “first” or “second” may explicitly or implicitly indicate that at least one such feature is included. In the description of the present disclosure, “a plurality” means at least two, such as two, three or more, unless otherwise specified.

The above is only the implementation modes of the present disclosure, which does not limit the patent scope of the present disclosure. Any equivalent structure or equivalent process transformation made by using the contents of the description and figures of the present disclosure, or directly or indirectly applied in other related technical fields, is similarly included in the patent protecting scope of the present disclosure.

What is claimed is:

1. A memory block, comprising:
a memory array, comprising a plurality of stacked strip structures and a plurality of semiconductor structures, the stacked strip structures being spaced apart from each other along a column direction; and each of the stacked strip structures extending along a row direction, and comprising a plurality of insulating strips and a plurality of conductive strips alternately stacked along a height direction; and
wherein some of the semiconductor structures are arranged between every two adjacent stacked strip structures, the every two adjacent stacked strip structures and some of the semiconductor structures arranged therebetween are involved in forming a row of memory subarray, the conductive strips in the every two adjacent stacked strip structures serve as control gates of the row of memory subarray; the row of memory subarray comprises a plurality of memory-cell groups distributed along the row direction, each memory-cell group comprises a corresponding semiconductor structure, the corresponding semiconductor structure extends along the height direction, and on a plane perpendicular to the height direction, a cross section of the corresponding semiconductor structure is ring-shaped.

2. The memory block according to claim 1, wherein
in each memory-cell group, the corresponding semiconductor structure comprises a source-region semiconductor structure, a drain-region semiconductor structure, a first channel semiconductor structure, and a second channel semiconductor structure; the first channel semiconductor structure and the second channel semiconductor structure are respectively arranged between the source-region semiconductor structure and the drain-region semiconductor structure; and
the source-region semiconductor structure, the drain-region semiconductor structure, the first channel semiconductor structure, and the second channel semiconductor structure extend along the height direction respectively.

3. The memory block according to claim 2, wherein
in each memory-cell group, the first channel semiconductor structure and the second channel semiconductor structure are bent in directions away from each other.

4. The memory block according to claim 2, wherein
in two adjacent stacked strip structures corresponding to each memory-cell group, each conductive strip serves as a control gate of the memory-cell group, to form a memory cell; and
the memory cell matches at least part of a corresponding conductive strip, a first/second channel semiconductor structure, the source-region semiconductor structure, and the drain-region semiconductor structure;
in the column direction, one of the two adjacent stacked strip structures arranged at a first side of the memory-cell group serves as a first stacked strip structure corresponding to the memory-cell group, the other of the two adjacent stacked strip structures arranged at a second side of the memory-cell group serves as a second stacked strip structure corresponding to the memory-cell group, and the first side is opposite to the second side;
each conductive strip in the first stacked strip structure serves as a first control gate of the memory-cell group, to form a first memory cell; and the first memory cell matches at least part of a corresponding conductive strip, the first channel semiconductor structure, the source-region semiconductor structure, and the drain-region semiconductor structure; and
each conductive strip in the second stacked strip structure serves as a second control gate of the memory-cell group, to form a second memory cell; and the second memory cell matches at least part of a corresponding conductive strip, the second channel semiconductor structure, the source-region semiconductor structure, and the drain-region semiconductor structure.

5. The memory block according to claim 4, wherein
each stacked strip structure at a non-edge region corresponds to two adjacent rows of memory subarrays;
each conductive strip in each stacked strip structure at the non-edge region serves as the first control gate of each memory-cell group in one of the two adjacent rows of memory subarrays, to form the first memory cell, and serves as the second control gate of each memory-cell group in the other of the two adjacent rows of memory subarrays, to form the second memory cell; and
each conductive strip in each stacked strip structure serves as a word line.

6. The memory block according to claim 2, wherein
each memory-cell group corresponds to two adjacent stacked strip structures; and
each memory-cell group further comprises a first memory structure and a second memory structure; the first memory structure is arranged between the corresponding semiconductor structure and one of the two adjacent stacked strip structures, bending directions of the first memory structure and the first channel semiconductor structure are the same as each other; the second memory structure is arranged between the corresponding semiconductor structure and the other of the two adjacent stacked strip structures, and bending directions of the second memory structure and the second channel semiconductor structure are the same as each other.

7. The memory block according to claim 6, wherein
the first memory structure and the second memory structure are charge-trapping memory structures respectively, and extend along the height direction respectively;
the first memory structure is arranged between one of the two adjacent stacked strip structures and the source-region semiconductor structure, the drain-region semiconductor structure, and the first channel semiconductor structure; and the second memory structure is arranged between the other of the two adjacent stacked strip structures and the source-region semiconductor structure, the drain-region semiconductor structure, and the second channel semiconductor structure; and
each of the first memory structure and the second memory structure comprises a first dielectric layer, a charge-trapping layer, and a second dielectric layer; the first dielectric layer is arranged between the charge-trapping layer and a corresponding stacked strip structures; the charge-trapping layer is arranged between the first dielectric layer and the second dielectric layer; and the second dielectric layer is arranged between the charge-trapping layer and the source-region semiconductor structure, the drain-region semiconductor structure, and a first/second channel semiconductor structure.

8. The memory block according to claim 6, wherein
each of the first memory structure and the second memory structure comprises a plurality of floating-gate memory structures distributed along the height direction; and each of the floating-gate memory structures is involved in forming a memory cell;
the first memory structure is arranged between one of the two adjacent stacked strip structures and the source-region semiconductor structure, the drain-region semiconductor structure, and the first channel semiconductor structure; the second memory structure is arranged between the other of the two adjacent stacked strip structures and the source-region semiconductor structure, the drain-region semiconductor structure, and the second channel semiconductor structure; and
each floating-gate memory structure comprises a floating gate and an insulating dielectric layer wrapping the floating gate; in the memory cell, a floating-gate memory structure is arranged between a corresponding conductive strip and a first/second channel semiconductor structure; and any surface of the floating gate is coated by the insulating dielectric layer.

9. The memory block according to claim 2, wherein
in each memory-cell group, a first insulating structure is arranged in an annular region enclosed by the source-region semiconductor structure, the drain-region semiconductor structure, the first channel semiconductor structure, and the second channel semiconductor structure cooperatively.

10. The memory block according to claim 2, wherein
in the row direction, a second insulating structure is arranged between the source-region semiconductor structure in one memory-cell group and the drain-region semiconductor structure in an adjacent memory-cell group, or the second insulating structure is arranged between the drain-region semiconductor structure in the one memory-cell group and the drain-region semiconductor structure in the adjacent memory-cell group; or
in the row direction, every two adjacent memory-cell groups comprise the drain-region semiconductor structure, the first channel semiconductor structure and the second channel semiconductor structure, the source-region semiconductor structure, another first channel semiconductor structure and another second channel semiconductor structure, and the drain-region semiconductor structure, and share the same source-region semiconductor structure; and the second insulating structure is arranged between the drain-region semiconductor structure in every two adjacent memory-cell groups and the drain-region semiconductor structure in another two adjacent memory-cell groups, and the another two adjacent memory-cell groups are adjacent to the every two adjacent memory-cell groups.

11. The memory block according to claim 1, wherein
the memory-cell groups in two adjacent rows of memory subarrays are aligned or misaligned with each other.

12. The memory block according to claim 2, wherein
in the height direction, among the conductive strips in a same layer, odd ones of the conductive strips are connected together, and even ones of the conductive strips are connected together;
the corresponding semiconductor structure in each memory-cell group further comprises a source-region-semiconductor connecting column, a drain-region-semiconductor connecting column, a first channel-semiconductor connecting column, and a second channel-semiconductor connecting column extending along the height direction;
in the height direction, the source-region-semiconductor connecting column is connected to the source-region semiconductor structure; the drain-region-semiconductor connecting column is connected to the drain-region semiconductor structure; the first channel-semiconductor connecting column is connected to the first channel semiconductor structure; and the second channel-semiconductor connecting column is connected to the second channel semiconductor structure; and
in a plurality of rows of memory subarrays, source-region semiconductor structures of the memory-cell groups in a same row are connected to a same source line through corresponding source-region-semiconductor connecting columns; drain-region semiconductor structures of the memory-cell groups in a same column are connected to a same bit line through corresponding drain-region-semiconductor connecting columns; first channel semiconductor structures and second channel semiconductor structures of the memory-cell groups in the same column are connected to a same well-region line through corresponding first channel-semiconductor connecting columns and corresponding second channel-semiconductor connecting columns.

13. The memory block according to claim 12, wherein
the source-region-semiconductor connecting column in each memory-cell group is further sleeved with a source-region conductive controlling ring; and source-region conductive controlling rings of the memory-cell groups in the same column are connected to a same source controlling line; and
the drain-region-semiconductor connecting column in each memory-cell groups is further sleeved with a drain-region conductive controlling ring; and drain-region conductive controlling rings of the memory-cell groups in the same column are connected to a same bit-line controlling line.

14. The memory block according to claim 13, wherein
the memory block is configured to receive a control signal and execute the following operations:
selecting all the odd or even ones of the conductive strips in one layer to apply a first word-line selecting voltage and executing a layer selection;
selecting one bit line to apply a first bit-line selecting voltage and executing a column selection; and
selecting one source line to apply a first source selecting voltage, executing a row selection, and selecting one memory cell to execute a read operation in coordination with the layer selection and the column selection.

15. The memory block according to claim 13, wherein
the memory block is configured to receive a control signal and execute the following operations:
selecting all the odd or even ones of the conductive strips in one layer to apply a second word-line selecting voltage and executing a layer selection;
selecting one source line to apply a second source selecting voltage and executing a row selection;
selecting one source controlling line, applying no source controlling voltage to the selected source controlling line, applying the source controlling voltage to other source controlling lines, and executing a column selection; and
selecting a bit-line controlling line to apply a bit-line controlling voltage, and selecting one memory cell to execute a programming operation in coordination with the layer selection, the row selection, and the column selection; and the selected bit-line controlling line and the selected source controlling line being connected to the memory-cell groups in the same column.

16. The memory block according to claim 13, wherein
well-region lines of the memory block are connected together;
the memory block is configured to receive a control signal and execute the following operations:
selecting all the odd or even ones of the conductive strips in each layer to apply a third word-line selecting voltage; and
applying an erasing voltage to all the well-region lines to execute an erasing operation on memory cells formed with a participation of all the odd or even ones of the conductive strips in each layer.

17. A memory-cell group, comprising:
a first memory cell, comprising a source-region semiconductor structure, a drain-region semiconductor structure, and a first channel semiconductor structure arranged between the source-region semiconductor structure and the drain-region semiconductor structure;
a second memory cell, comprising the source-region semiconductor structure, the drain-region semiconductor structure, and a second channel semiconductor structure arranged between the source-region semiconductor structure and the drain-region semiconductor structure;
wherein the first memory cell and the second memory cell share the source-region semiconductor structure and the drain-region semiconductor structure; and
the source-region semiconductor structure, the drain-region semiconductor structure, the first channel semiconductor structure, and the second channel semiconductor structure form an annular structure cooperatively.

18. The memory-cell group according to claim 17, wherein
the first channel semiconductor structure and the second channel semiconductor structure are arranged in arc shapes respectively and bent in directions away from each other.

19. The memory-cell group according to claim 17, wherein
the first memory cell further comprises a first conductive strip arranged at a first side of the memory-cell group, and the first conductive strip serves as a control gate of the first memory cell; and the second memory cell further comprises a second conductive strip arranged at a second side of the memory-cell group, and the second conductive strip serves as a control gate of the second memory cell, and the first side is opposite to the second side.

20. A memory device, comprising one or more memory blocks, wherein each memory block comprises:
a memory array, comprising a plurality of stacked strip structures and a plurality of semiconductor structures, the stacked strip structures being spaced apart from each other along a column direction; and each of the stacked strip structures extending along a row direction, and comprising a plurality of insulating strips and a plurality of conductive strips alternately stacked along a height direction; and
wherein some of the semiconductor structures are arranged between every two adjacent stacked strip structures, the every two adjacent stacked strip structures and some of the semiconductor structures arranged therebetween are involved in forming a row of memory subarray, the conductive strips in the every two adjacent stacked strip structures serve as control gates of the row of memory subarray; the row of memory subarray comprises a plurality of memory-cell groups distributed along the row direction, each memory-cell group comprises a corresponding semiconductor structure, the corresponding semiconductor structure extends along the height direction, and on a plane perpendicular to the height direction, a cross section of the corresponding semiconductor structure is ring-shaped.
